(19) United States
(12) Patent Application Publication
(10) Pub. No.: US 2025/0303923 A1
(43) Pub. Date: Oct. 2, 2025

(54) CONTROL DEVICE

(71) Applicant: TOYOTA JIDOSHA KABUSHIKI KAISHA, Toyota-shi (JP)

(72) Inventor: Yuki SUGO, Seto-shi (JP)

(73) Assignee: TOYOTA JIDOSHA KABUSHIKI KAISHA, Toyota-shi (JP)

(21) Appl. No.: 19/063,413

(22) Filed: Feb. 26, 2025

(30) Foreign Application Priority Data
Mar. 29, 2024 (JP) 2024-057183

(51) Int. Cl. B60L 58/16; G01R 31/387; G01R 31/392; H01M 10/48

(52) U.S. Cl. CPC B60L 58/16; G01R 31/387; G01R 31/392; B60L 2250/00; H01M 10/488; H01M 2220/20

(57) ABSTRACT

A server includes a processor that updates a degradation coefficient of a power storage device, and a communication unit. In a case where an estimated value of a capacity of the power storage device is increased by update of the degradation coefficient, the communication unit performs a notification process for notifying a user that the degradation coefficient is updated, and the processor updates the degradation coefficient. In a case where the estimated value is decreased by update of the degradation coefficient, the communication unit does not perform the notification process, and the processor updates the degradation coefficient by gradually changing the degradation coefficient.

### CROSS REFERENCE TO RELATED APPLICATIONS

This nonprovisional application is based on Japanese Patent Application No. 2024-057183 filed on Mar. 29, 2024 with the Japan Patent Office, the entire contents of which are hereby incorporated by reference.

### BACKGROUND

### Field

The present disclosure relates to a control device.

### Description of the Background Art

Japanese Patent Laying-Open No. 2020-065423 discloses a vehicle provided with a display unit indicating a display value corresponding to a degradation state of a battery.

### SUMMARY

A degradation coefficient of the battery may be used for estimating the degradation state (capacity) of the battery, which, however, is not disclosed in Japanese Patent Laying-Open No. 2020-065423 referenced above. The degradation coefficient may be updated as required. In this case, an estimated value of the capacity of the battery changes as the degradation coefficient of the battery is updated. A user of the vehicle may feel strange about a sudden change of the capacity of the battery.

The present disclosure is given to solve the above problem, and an object of the present disclosure is to provide a control device capable of preventing a user from feeling strange about a change of the capacity of a battery mounted on a vehicle as the degradation coefficient of the battery is updated.

A control device according to one aspect of the present disclosure is a control device that updates a degradation coefficient of a battery mounted on a vehicle, the degradation coefficient being used for calculating an estimated value of a capacity of the battery. The control device includes an update unit that updates the degradation coefficient, and a notification unit. A user of the vehicle is informed, by an informing device, of at least one of the estimated value and a capacity retention of the battery based on the estimated value. In a first case where the estimated value is increased by update of the degradation coefficient, the notification unit performs a notification process for notifying the user that the degradation coefficient is upd, and the update unit updates the degradation coefficient. In a second case where the estimated value is decreased by update of the degradation coefficient, the notification unit does not perform the notification process, and the update unit updates the degradation coefficient by gradually changing the degradation coefficient.

Regarding the control device according to one aspect of the present disclosure, in the first case where the estimated value is increased by update of the degradation coefficient, the notification unit performs the notification process for notifying the user that the degradation coefficient is updated, and the update unit updates the degradation coefficient. Thus, the user acquires the information that the degradation coefficient is updated, and therefore, even when the estimated value of the capacity is changed by update of the degradation coefficient, the user can be prevented from feeling strange. In the second case where the estimated value of the capacity is decreased by update of the degradation coefficient, the notification unit does not perform the notification process, and the update unit updates the degradation coefficient by gradually changing the degradation coefficient. Thus, the gradual change of the degradation coefficient can cause the estimated value of the capacity to be changed gradually. As a result, it is difficult for the user to recognize that the estimated value has been decreased, which makes it possible to prevent the user from feeling strange about the change of the estimated value of the capacity.

In the first case, the update unit may update the degradation coefficient after the notification process is performed by the notification unit. Such a configuration enables the user to know in advance that the estimated value will change, before the estimated value of the capacity is changed by update of the degradation coefficient. As a result, it is possible to more effectively prevent the user from feeling strange about the change of the estimated value of the capacity.

In the second case, the update unit may gradually change the degradation coefficient by changing the degradation coefficient step by step. Such a configuration enables the degradation coefficient to be updated by updating it step by step (intermittently) rather than updating it continuously. As a result, the process load on the update unit can be reduced, as compared with the case where the update unit updates it continuously.

In the second case, the update unit may update the degradation coefficient by gradually changing the degradation coefficient, when a decrease of the estimated value caused by update of the degradation coefficient is larger than a threshold value, and may update the degradation coefficient without gradually changing the degradation coefficient, when the decrease is less than or equal to the threshold value. In the case where a decrease of the capacity is relatively larger so that the user is more likely to feel strange about the decrease, such a configuration enables the degradation coefficient to be changed more gradually and, in the case where a decrease of the capacity is relatively smaller so that the user is less likely to feel strange about the change, such a configuration enables the degradation coefficient to be changed more quickly.

The informing device may include a display terminal. In the first case, the notification unit may perform the notification process in such a manner that information that the degradation coefficient is updated is displayed on the display terminal. Such a configuration enables reduction of the number of terminals required by the user, as compared with the case where a terminal displaying the information that the degradation coefficient is updated is separate from the display terminal.

The foregoing and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a diagram illustrating a configuration of a system including an electrically powered vehicle and a server according to one embodiment.

FIG. 2 is a diagram showing a display screen of the car navigation device of the electrically powered vehicle according to one embodiment.

FIG. 3 is a sequence diagram illustrating control in the system according to one embodiment.

FIG. 4 is a diagram showing a display screen of the car navigation device in step S12 of FIG. 3.

FIG. 5 is a diagram showing a change in the degradation coefficient in step S6 of FIG. 3.

FIG. 6 is a diagram showing a change in the degradation coefficient in step S7 of FIG. 3.

FIG. 7 is a diagram illustrating a change in a degradation coefficient according to a modification of one embodiment.

### DESCRIPTION OF THE PREFERRED EMBODIMENTS

Hereinafter, embodiments of the present disclosure will be described in detail with reference to the drawings. In the drawings, the same or corresponding parts are denoted by the same reference numerals, and the description thereof will not be repeated.

### System Configuration

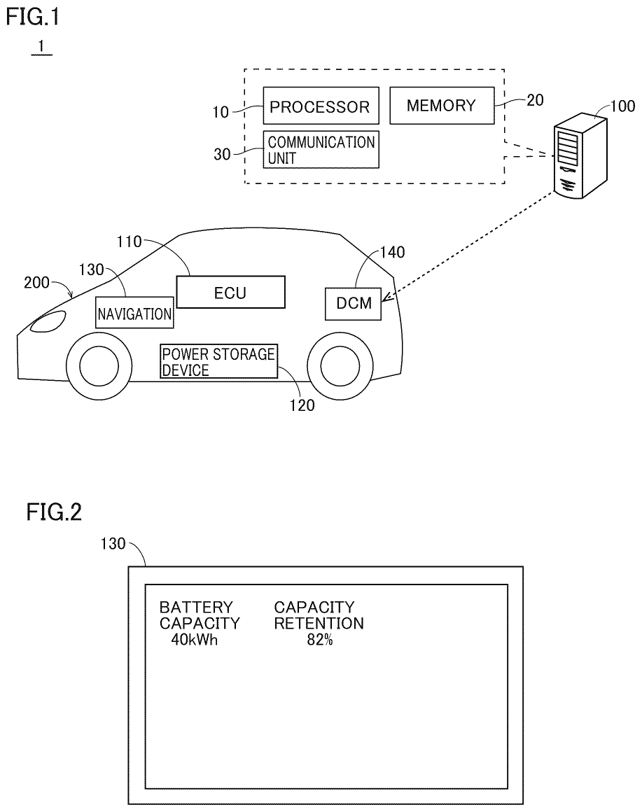

FIG. 1 is a diagram illustrating a configuration of a system 1 including a server (control device) 100 and an electrically powered vehicle (vehicle) 200 according to the present embodiment. The server 100 and the electrically powered vehicle 200 are examples of the “control device” and the “vehicle” of the present disclosure, respectively.

The electrically powered vehicle 200 is, for example, PHEV (Plug-in Hybrid Electric Vehicle), BEV (Battery Electric Vehicle), or FCEV (Fuel Cell Electric Vehicle).

Electrically powered vehicle 200 includes ECU (Electronic Control Unit) 110, power storage device (battery) 120, car navigation device (informing device) (display device) 130, and DCM (Data Communication Module) 140. The power storage device 120 is an example of the “battery” in the present disclosure. The car navigation device 130 is an example of the “informing device” and the “display terminal” of the present disclosure.

The ECU 110 executes processes related to various types of vehicle control. For example, the ECU 110 performs a process of estimating the capacity of the power storage device 120 using the degradation coefficient of the power storage device 120. The degradation coefficient is stored in a memory (not shown) of the ECU 110. In this specification, the estimated value of the capacity of the power storage device 120 is simply referred to as a “battery capacity”. The battery capacity means the amount of electricity at the time of full charge.

The degradation coefficient stored in the ECU 110 is updated by the server 100. Specifically, the degradation coefficient stored in the ECU 110 is rewritten based on the updated degradation coefficient information transmitted from the server 100 to the electrically powered vehicle 200 by an over the air (OTA). As a result, the change in the degradation coefficient in the server 100 is reflected in the degradation coefficient stored in the ECU 110. The ECU 110 may calculate an estimated value of the capacity retention of the power storage device 120 (hereinafter simply referred to as a “capacity retention”) based on the estimated battery capacity. The capacity retention means the ratio of the current battery capacity to the battery capacity at the time of manufacturing.

Electric power for driving the electrically powered vehicle 200 is stored in the power storage device 120. The power storage device 120 accommodates a plurality of power storage cells. The power storage cell is a secondary battery, typically a lithium-ion secondary battery. The lithium-ion secondary battery is a battery in which lithium is used as a charge carrier. The lithium-ion secondary battery may include not only a lithium-ion secondary battery in which an electrolyte is a liquid but also an all-solid-state battery using a solid electrolyte. Note that the power storage cell is not limited to a lithium-ion secondary battery. The power storage cell may be configured by a nickel-metal hydride secondary battery or other secondary batteries.

Referring to FIG. 2, car navigation device 130 displays a battery capacity and a capacity retention. Note that only one of the battery capacity and the capacity retention may be displayed on the car navigation device 130.

Referring back to FIG. 1, the DCM 140 is configured to communicate with the server 100 (a communication unit 30 described later). Accordingly, the electrically powered vehicle 200 acquires various kinds of information (for example, update information of the degradation coefficient) from the server 100 through the DCM 140.

The server 100 includes a processor (update unit) 10, a memory 20, and a communication unit (notification unit) 30. The processor 10 controls the communication unit 30. The memory 20 stores not only a program executed by the processor 10 but also information (for example, a map, a mathematical expression, and various parameters) used in the program. The processor 10 and the communication unit 30 are examples of the “update unit” and the “notification unit” of the present disclosure, respectively.

The communication unit 30 is configured to communicate with the DCM 140 of the electrically powered vehicle 200. The communication unit 30 may be capable of communicating with an external server or the like (not shown) through the Internet.

The processor 10 executes a process for updating the degradation coefficient stored in the ECU 110 of the electrically powered vehicle 200. Further, the processor 10 determines whether it is necessary to update the degradation coefficient based on the information received by the communication unit 30. When it is determined that the degradation coefficient needs to be updated, the processor 10 performs a process of updating the degradation coefficient.

The case where the degradation coefficient needs to be updated includes, for example, a case where it is found that the degradation coefficient corresponding to the power storage device 120 needs to be corrected because the power storage cell of the power storage device 120 is a lower limit product (or an upper limit product) in the lot. Alternatively, the case where the update of the degradation coefficient is necessary includes, for example, a case where it is found that the modification of the degradation coefficient corresponding to the power storage device 120 is necessary due to the update of various programs (software) related to the calculation of the degradation coefficient.

The server 100 (processor 10) executes a process of updating the degradation coefficient when the electrically powered vehicle 200 is stopped, for example. The case where the electrically powered vehicle 200 is stopped includes a case where the stop time of the electrically powered vehicle 200 is predicted to be 30 minutes or more, for example.

Here, since the battery capacity changes along with the update of the degradation coefficient, the user of the electrically powered vehicle 200 may feel strange about the sudden change in the battery capacity.

Therefore, in the present embodiment, when the battery capacity increases due to the degradation coefficient being updated, the communication unit 30 executes a notification process for notifying the user that the degradation coefficient is updated, and the processor 10 updates the degradation coefficient. Thus, the user can recognize that the battery capacity (capacity retention) has changed with the update of the degradation coefficient. As a result, it is possible to prevent the user from feeling strange about a change in the battery capacity (capacity retention).

When the battery capacity decreases due to the degradation coefficient being updated, the communication unit 30 does not execute the notification process, and the processor 10 updates the degradation coefficient by gradually changing the degradation coefficient. As a result, the battery capacity (capacity retention) can be gradually decreased as the degradation coefficient gradually changes. As a result, it is possible to make it difficult for the user to recognize that the battery capacity (capacity retention) has decreased. Accordingly, it is possible to prevent the user from feeling strange about a change in the battery capacity (capacity retention).

### Server and Sequence Control of Electrically Powered Vehicle

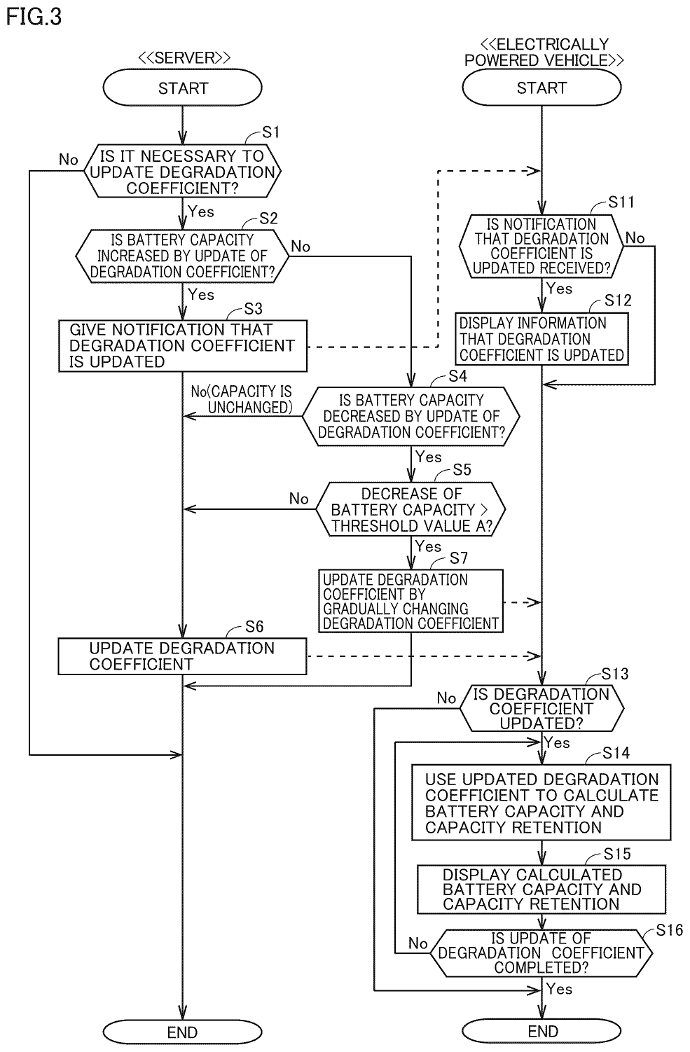

FIG. 3 shows a sequence diagram of control by the server 100 and the electrically powered vehicle 200. The sequence shown in FIG. 3 may be executed (started) every predetermined period (for example, 10 minutes).

In step S1, the server 100 (processor 10) determines whether it is necessary to update the degradation coefficient of the power storage device 120. When it is determined that the degradation coefficient needs to be updated (Yes in S1), the process proceeds to step S2. When it is determined that the update of the degradation coefficient is not necessary (No in S1), the process ends.

In step S2, the server 100 (processor 10) determines whether or not the battery capacity is increased by update of the degradation coefficient. Specifically, the server 100 determines whether or not the battery capacity calculated using the degradation coefficient after the update is larger than the battery capacity calculated using the degradation coefficient before the update. When the battery capacity increases (Yes in S2), the process proceeds to step S3. When the battery capacity does not increase (No in S2), the process proceeds to step S4.

In step S3, the server 100 (communication unit 30) executes a notification process for notifying the user that the degradation coefficient is updated. Specifically, the communication unit 30 transmits information that the degradation coefficient is updated to the DCM 140 (FIG. 1) of the electrically powered vehicle 200. Next, the process proceeds to step S6.

In step S4, the server 100 (processor 10) determines whether or not the battery capacity is decreased by the update of the degradation coefficient. Specifically, the server 100 determines whether or not the battery capacity calculated using the degradation coefficient after the update is smaller than the battery capacity calculated using the degradation coefficient before the update. When the battery capacity decreases (Yes in S4), the process proceeds to step S5. When the battery capacity does not decrease (that is, the battery capacity does not change) (No in S4), the process proceeds to step S6.

In step S5, the server 100 (processor 10) determines whether or not the decrease in battery capacity due to the update of the degradation coefficient is greater than a predetermined threshold A. The threshold A may be a fixed value. Alternatively, the threshold A may be, for example, a predetermined ratio (for example, 10%) of the battery capacity at present (before update). When the decrease of the battery capacity is larger than the threshold A (Yes in S5), the process proceeds to step S7. When the decrease in battery capacity is equal to or less than threshold A (No in S5), the process proceeds to step S6. The threshold A is an example of the “threshold” in the present disclosure.

In step S6, the processor 10 executes a process of updating the degradation coefficient. Thus, the degradation coefficient stored in the memory (not shown) of the ECU 110 (FIG. 1) is updated (rewritten) by the OTA through the communication unit 30 and the DCM 140. The process then ends.

In step S7, the processor 10 executes a process of updating the degradation coefficient by gradually changing the degradation coefficient. As a result, the degradation coefficient stored in the electrically powered vehicle 200 is gradually changed. Also in step S7, similarly to step S6, a process of updating the degradation coefficient by the OTA is executed. The process then ends.

In step S11, the electrically powered vehicle 200 (ECU 110) determines whether the DCM 140 has received a notification (notification in S3) that the degradation coefficient is updated. When the notification is received (Yes in S11), the process proceeds to step S12. When the notification is not received (No in S11), the process proceeds to step S13.

In step S12, electrically powered vehicle 200 (ECU 110) causes car navigation device 130 (FIG. 1) to display information that the degradation coefficient is updated.

In step S13, the electrically powered vehicle 200 (ECU 110) determines whether or not the degradation coefficient has been updated (changed). When the degradation coefficient is updated (changed) (Yes in S13), the process proceeds to step S14. When the degradation coefficient is not updated (changed) (No in S13), the process ends.

In step S14, the electrically powered vehicle 200 (ECU 110) calculates the battery capacity and the capacity retention using the updated (changed) degradation coefficient.

In step S15, electrically powered vehicle 200 (ECU 110) causes car navigation device 130 to display the battery capacity and the capacity retention calculated in step S14.

In step S16, the electrically powered vehicle 200 (ECU 110) determines whether the update of the degradation coefficient has been completed. The case where the update of the degradation coefficient is not completed is a case where the degradation coefficient is scheduled to be further changed in step S7. For example, the electrically powered vehicle 200 may determine that the update of the degradation coefficient has been completed based on that the degradation coefficient has not changed for a predetermined time (for example, 30 minutes) or more. When it is determined that the update of the degradation coefficient is completed (Yes in S16), the process ends. When it is determined that the update of the degradation coefficient is not completed (No in S16), the process returns to step S14. The method of determining whether the update of the degradation coefficient is completed is not limited to the above example.

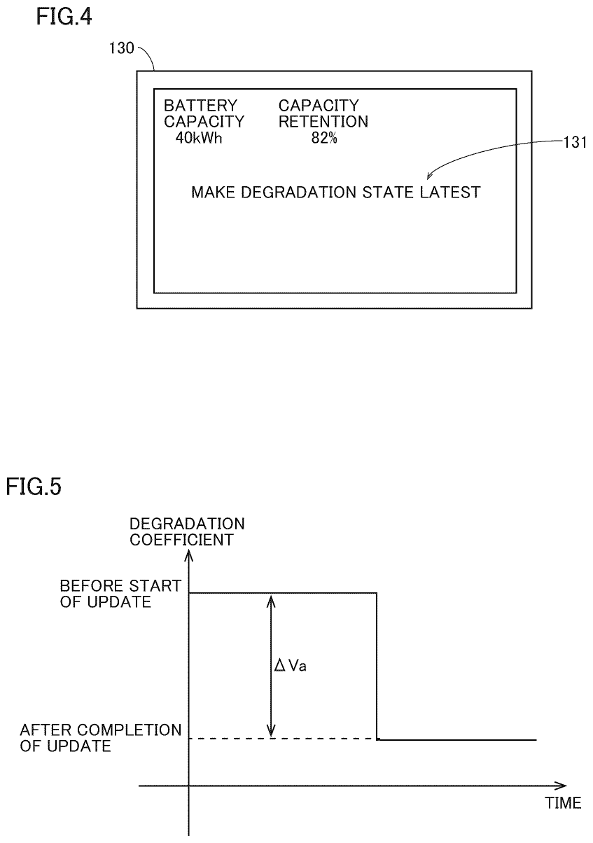

FIG. 4 is a diagram showing an example of a display screen of the car navigation device 130 in step S12. The car navigation device 130 displays a message 131 in which “Make the degradation state the latest” is described. This notifies the user that the degradation coefficient is updated.

FIG. 5 is a diagram showing how the degradation coefficient changes due to the update of the degradation coefficient in step S6. In step S6, the degradation coefficient changes from the value before the start of the update to the value after the completion of the update by instantaneously changing. In other words, the degradation coefficient is changed to the value after the update is completed by adding the predetermined value ΔVa to the value before the update is started (the degradation coefficient after the update is completed=the degradation coefficient before the update is started+ΔVa). That is, in the update process of step S6, the number of times the value of the degradation coefficient changes is one. Note that the magnitude relationship between the degradation coefficient before completion of update and the degradation coefficient after completion of update is not described in the present embodiment.

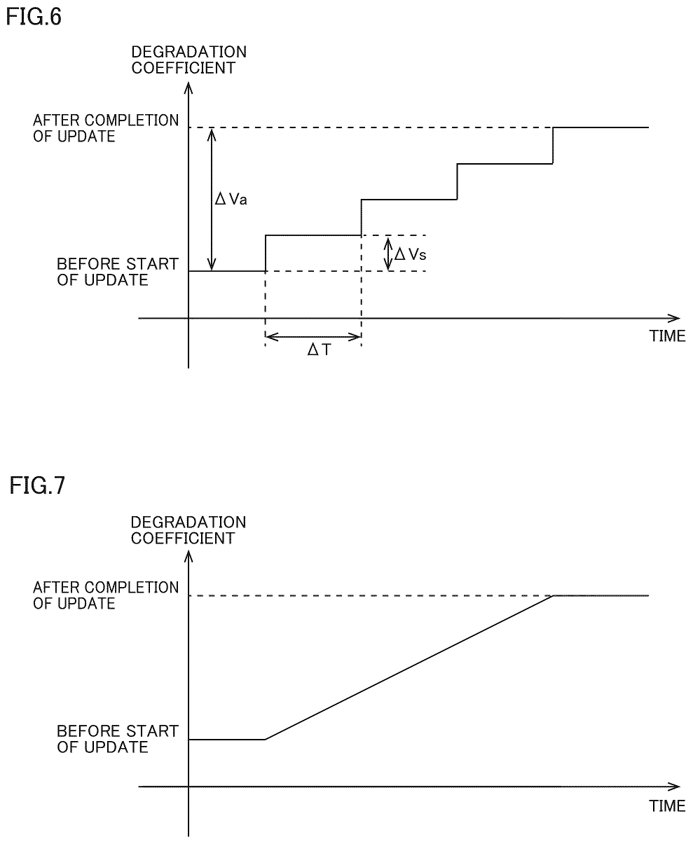

FIG. 6 is a diagram showing how the degradation coefficient changes due to the update of the degradation coefficient in step S7. In step S7, the degradation coefficient changes from the value before the start of the update to the value after the completion of the update in a stepwise manner. In the example shown in FIG. 6, the degradation coefficient changes in four stages. In this case, the degradation coefficient changes by ΔVa/4, for example, every one stage. That is, the change amount ΔVs in one stage is ΔVa/4. The number of changes (the number of stages) in the degradation coefficient in step S7 is not limited to four. The stepwise change of the degradation coefficient is an example of “to gradually change the degradation coefficient” in the present disclosure.

In step S7, the degradation coefficient changes every cycle of ΔT (for example, 30 minutes). Therefore, it is necessary to change the degradation coefficient from the degradation coefficient before the start of the update to the degradation coefficient after the completion of the update by 3×ΔT. The value of ΔT is not limited to the above example.

At least one of the number of changes in the degradation coefficient (the number of stages), ΔVs, and ΔT may be a preset fixed value. Further, at least one of the above may be changed according to a predetermined condition. For example, at least one of the above may be variable based on the magnitude of ΔVa, the magnitude of the degradation coefficient before the start of the update (or after the completion of the update), and the like.

As described above, in the present embodiment, when the battery capacity increases as the degradation coefficient is updated, the communication unit 30 executes a notification process for notifying the user that the degradation coefficient is updated, and the processor 10 updates the degradation coefficient. Thus, the user can recognize that the battery capacity has increased as the degradation coefficient is updated.

In addition, in the present embodiment, when the battery capacity decreases due to the degradation coefficient being updated, the communication unit 30 does not execute the notification process, and the processor 10 updates the degradation coefficient by gradually changing the degradation coefficient. Accordingly, it is possible to suppress the user from recognizing (noticing) that the battery capacity is decreasing. Therefore, the battery capacity can be reduced so as not to cause the user to feel strange.

Accordingly, it is possible to prevent the user from feeling strange about the change in the battery capacity accompanying the update of the degradation coefficient.

In the above embodiment, an example in which the degradation coefficient is changed stepwise when the battery capacity decreases due to the update of the degradation coefficient has been described, but the present disclosure is not limited thereto. The degradation coefficient may change continuously. For example, in the example shown in FIG. 7, when the battery capacity decreases due to the update of the degradation coefficient, the degradation coefficient linearly changes from the value before the start of the update to the value after the completion of the update. The degradation coefficient may not change linearly, but may change in a quadratic manner, for example. The continuous change of the degradation coefficient is an example of “to gradually change the degradation coefficient” in the present disclosure.

Although an example in which the degradation coefficient is updated after the user is notified that the degradation coefficient is updated has been described in the above embodiment, the present disclosure is not limited thereto. The degradation factor may be updated simultaneously with or prior to the notification to the user.

In the above-described embodiment, an example has been described in which, when the battery capacity increases due to the update of the degradation coefficient, the degradation coefficient instantaneously (in one change) changes to a value after completion of the update, but the present disclosure is not limited thereto. Even when the battery capacity increases due to the update of the degradation coefficient, the degradation coefficient may be gradually changed as in the case where the battery capacity decreases.

In the above embodiment, an example in which the degradation coefficient is not gradually changed when the decrease in the battery capacity due to the update of the degradation coefficient is equal to or less than the threshold A has been described, but the present disclosure is not limited thereto. The degradation coefficient may be gradually changed regardless of the decrease in the battery capacity due to the update of the degradation coefficient.

Although an example in which the battery capacity and the capacity retention are displayed on the car navigation device 130 has been described in the above embodiment, the present disclosure is not limited thereto. The battery capacity and the capacity retention may be displayed on a terminal of the user (such as a smartphone and a PC). Information that the degradation coefficient is updated may also be displayed on the terminal of the user. In addition, information that the battery capacity, the capacity retention, and the degradation coefficient are updated may be given by voice.

In the above embodiment, the example in which the battery capacity and the capacity retention and the information that the degradation coefficient is updated are displayed on the same car navigation device 130 has been described, but the present disclosure is not limited thereto. The battery capacity and the capacity retention and the information that the degradation coefficient is updated may be displayed on different display terminals (for example, a car navigation device and a smartphone).

In the above embodiment, an example has been described in which the degradation coefficient stored in the ECU 110 of the electrically powered vehicle 200 gradually changes by reflecting the information of the degradation coefficient gradually changed in the server 100 on the degradation coefficient stored in the ECU 110 of the electrically powered vehicle 200, but the present disclosure is not limited thereto. For example, the ECU (processor) of the vehicle that has acquired the information of the degradation coefficient after the completion of the update from the server may gradually change the degradation coefficient stored in the memory of the ECU. In this case, the ECU of the vehicle is an example of the “control device” of the present disclosure.

Although an example in which the degradation coefficient is updated by the OTA has been described in the above embodiment, the present disclosure is not limited thereto. For example, the degradation coefficient may be updated by wire in a dealer or the like.

In the above embodiment, an example in which the degradation coefficient is updated even when the battery capacity does not change due to the update of the degradation coefficient has been described, but the present disclosure is not limited thereto. In this case, it is not necessary to update the degradation coefficient.

Although an example in which the battery capacity and the capacity retention calculated in the electrically powered vehicle 200 are displayed on the car navigation device 130 has been described in the above embodiment, the present disclosure is not limited thereto. The battery capacity and the capacity retention calculated in the server 100 may be displayed on the car navigation device 130 as they are.

In the above embodiment, an example has been described in which the degradation coefficient stored in the ECU 110 of the electrically powered vehicle 200 is updated by transmitting the information of the degradation coefficient after the update to the electrically powered vehicle 200, but the present disclosure is not limited thereto. For example, the degradation coefficient stored in the ECU of the vehicle may be updated by transmitting an update program for calculating the degradation coefficient from the server to the vehicle.

Note that the configurations (processes) of the above-described embodiments and the above-described modifications may be combined with each other.

Although the present disclosure has been described and illustrated in detail, it is clearly understood that the same is by way of illustration and example only and is not to be taken by way of limitation, the scope of the present disclosure being interpreted by the terms of the appended claims.

What is claimed is:

1. A control device that updates a degradation coefficient of a battery mounted on a vehicle, the degradation coefficient being used for calculating an estimated value of a capacity of the battery, the control device comprising:
an update unit that updates the degradation coefficient; and
a notification unit, wherein
a user of the vehicle is informed, by an informing device, of at least one of the estimated value and a capacity retention of the battery based on the estimated value,
in a first case where the estimated value is increased by update of the degradation coefficient,
the notification unit performs a notification process for notifying the user that the degradation coefficient is updated, and
the update unit updates the degradation coefficient, and
in a second case where the estimated value is decreased by update of the degradation coefficient,
the notification unit does not perform the notification process, and
the update unit updates the degradation coefficient by gradually changing the degradation coefficient.

2. The control device according to claim 1, wherein in the first case, the update unit updates the degradation coefficient after the notification process is performed by the notification unit.

3. The control device according to claim 1, wherein in the second case, the update unit gradually changes the degradation coefficient by changing the degradation coefficient step by step.

4. The control device according to claim 1, wherein
in the second case, the update unit
updates the degradation coefficient by gradually changing the degradation coefficient, when a decrease of the estimated value caused by update of the degradation coefficient is larger than a threshold value, and
updates the degradation coefficient without gradually changing the degradation coefficient, when the decrease is less than or equal to the threshold value.

5. The control device according to claim 1, wherein
the informing device includes a display terminal, and
in the first case, the notification unit performs the notification process in such a manner that information that the degradation coefficient is updated is displayed on the display terminal.
